(19) United States
(12) Patent Application Publication
(10) Pub. No.: US 2003/0024111 A1
(43) Pub. Date: Feb. 6, 2003

(54) Dot penetration method for inter-layer connections of electronic components

(75) Inventors: Daniel H. Chang, Rancho Santa Fe, CA (US); Xiang-Ming Li, San Diego, CA (US); Liwu Wang, San Diego, CA (US)

Correspondence Address: LIU & LIU LLP, 811 WEST SEVENTH STREET, SUITE 1100, LOS ANGELES, CA, 90017, US

(73) Assignee: AEM, Inc., San Diego, CA

(21) Appl. No.: 10/211,486

(22) Filed: Aug. 2, 2002

Related U.S. Application Data
(60) Provisional application No. 60/309,801, filed on Aug. 2, 2001.

(51) Int. Cl. H05K 3/36; H05K 3/20

(52) U.S. Cl. 29/831; 29/830; 29/846

(57) ABSTRACT

A multilayered electronic component with inter-layer connections is created by a process using dot penetration techniques. Electrodes are formed on a substrate. One or more conductive structures are formed on the electrodes to provide for interlayer electrical connections. A non-conductive (e.g., ceramic) sheet is laminated on top of the conductive dots under elevated pressure and temperature to cause the dot to penetrate through the ceramic sheet. A second electrode is printed on top of the penetrated conductive structure to complete the interlayer electrical connection without having to punch holes to form vias in the ceramic sheet.

### BACKGROUND OF THE INVENTION

1. Field of the Invention

The present invention relates generally to a process of manufacturing multi-layer electronic components with electrodes embedded in ceramics, and in particular a process for making inter-layer connections in such multi-layer electronic components using a dot penetration technique.

2. Description of Related Art

A multi-layer electronic component often contains both conductive and nonconductive layers. It is sometimes required to form inter-layer electrical connections between the conductive layers to produce electronic components with the desired electrical characteristics. Examples of multi-layered electronic components include multi-layered ceramic capacitors (MLCC) and multi-layer ceramic inductors (MLCI). Some multi-layer components, like inductors, multi-chip modules, passive integration devices, integrated circuit packaging, filters, transformers, chokes and chip beads, may require inter-layer electrical connection between electrodes at different layers. There are a few existing processes for manufacturing multi-layer electronic components.

A semi-wet process is disclosed in U.S. Pat. No. 4,322,698 to Takahashi et al. Dry sheets are made for the top and bottom ceramic layers, but a wet process is used to print electrodes and ceramic layers in between. The inter-layer connections are made with printing of ceramic paste on top of electrode except at the inter-layer connection points. Subsequent printing of electrode on top of the uncovered portion of electrode completes the inter-layer connections. This process involves many process steps and many pieces of major equipment (tape casting, tape cutting, tape peeling, tape pressing, printing for both ceramic and electrode active layers, drying, tape stacking, and tape lamination) to complete the buildup. This process does not fair well for fabricating small components.

A dry sheet process is disclosed in U.S. Pat. No. 5,032,815 to Kobayashi et al. Dry sheets of ceramic green tapes with electrodes printed thereon are used as the basic parts of the electronic components. These ceramic tapes and electrode materials are made of ceramic and metal powder respectively bound together by polymer binders. These dry sheets are laminated at elevated temperatures and high pressure. To allow inter-layer connections, holes are punched on the ceramic tape and filling of metal powder ink in those holes are necessary to form vias. After the structure is formed, a burnout process is required to remove/decompose the binder and a firing process is required to sinter the ceramic powder and metal powder to provide the desired physical and electrical properties. This process involves many steps and many pieces of major equipment (tape casting, tape cutting, via punching, via filling, electrode printing, tape peeling, tape stacking, and lamination) to complete the buildup for the component. The low speed of punching and wear and tear of the tooling are some of the major drawbacks of this process.

A wet process is disclosed in U.S. Pat. No. 5,650,199 to Chang et al. A curtain coater or similar devices are used to lay down ceramic coatings in slurry form on pallets or bars to build multilayer ceramic components. Each layer of coating sticks to those above and below it without the need for lamination, which is required in both the dry sheet and semi-wet process. When using a wet buildup process for making an interlayer connection, a dot, made of a metal ink, is printed on top of the electrode, which has been printed on top of a ceramic layer that rests on a pallet, at the location where a connection to the upper adjacent electrode is desired. A thin layer of ceramic slurry coating is then applied on the top of the pallet by using a curtain coater. Due to the chemical-physical incompatibility of the dot ink and ceramic slurry, vias or holes, which are occupied by the dot ink, are formed on the ceramic coating layer.

The wet process requires at least two major steps (coating and printing) and at least three pieces of major equipment (coating, drying, and printing) to complete the buildup process. Compared to the dry sheet and semi-wet processes, the wet process significantly reduces the process steps and labor costs. However, because the layers are generally wet when they are stacked against each other, there is an interaction between the solvents in different layers exists, which can cause an undesirable non-uniform drying of the green bars, hence reducing the yield of the production. Since the curtain coating follows the contour of the prints, it is difficult to obtain flat and even surface. The uneven surface could further affect subsequent printing and via forming. This process does not fair well for small parts with high layer counts.

It is desirable to provide an improved process for forming multi-layer electronic components, which overcomes the drawbacks in the prior art.

### SUMMARY OF THE INVENTION

The present invention overcomes the drawbacks of the prior art by using a penetration process rather than hole punching or via formation to form conductive interlayer connections of two conductive layers (e.g., a pattern of electrodes) through a nonconductive layer. Multiple layers of non-conductive sheets having electrodes and penetrated conductive dots may be configured to form a variety of multi-layer electronic components (e.g., ceramic inductors, filters, transformers, chokes, multi-chip modules, passive integration devices, IC packaging, chip beads, etc).

According to one aspect of the present invention, continuous prefabricated Ceramic Green Sheets (CGS) are used rather than a wet ceramic slurry or a ceramic sheet having punched via holes. An electrode is formed on a substrate to form the electrical conduit for a desired electronic component. The substrate could include a top layer of CGS. An electrical interconnection structure is formed on top of the electrode, such as by printing and curing an electrode ink dot. A layer of CGS is laminated on top of the interconnection structure under elevated temperature and pressure to cause the structure to penetrate through the CGS. An additional electrode is formed on top of the CGS layer to complete the desired interlayer connection.

In another aspect of the present invention, multiple electrodes, dots, and CGS's are formed to create multiple interlayer connections according to the process of the present invention to form a monolithic structure.

### BRIEF DESCRIPTION OF THE DRAWINGS

FIG. 1 illustrates a first layer of CGS on a substrate;

FIG. 2 illustrates an electrode printed on the first layer of CGS;

FIG. 3 illustrates the first layer of CGS and electrode of FIG. 2 with a printed dot with conductive ink for interlayer electrical connection;

FIG. 4 illustrates a second layer of CGS being laminated on top of the printed dot of FIG. 3;

FIG. 5 illustrates the penetration of the printed dot through the second layer of CGS;

FIG. 6 illustrates an interlayer connection between two electrodes; and

FIG. 7 illustrates the process flow of the dot penetration method of the present invention.

### DETAILED DESCRIPITION OF THE PREFERRED EMBODIMENT

This invention is described in a preferred embodiment in the following description with references to the attached drawings. While this invention is described in terms of the best mode of achieving this invention's objectives, it will be appreciated by those skilled in the art that variations may be accomplished in view of these teachings without deviating from the spirit or scope of the invention.

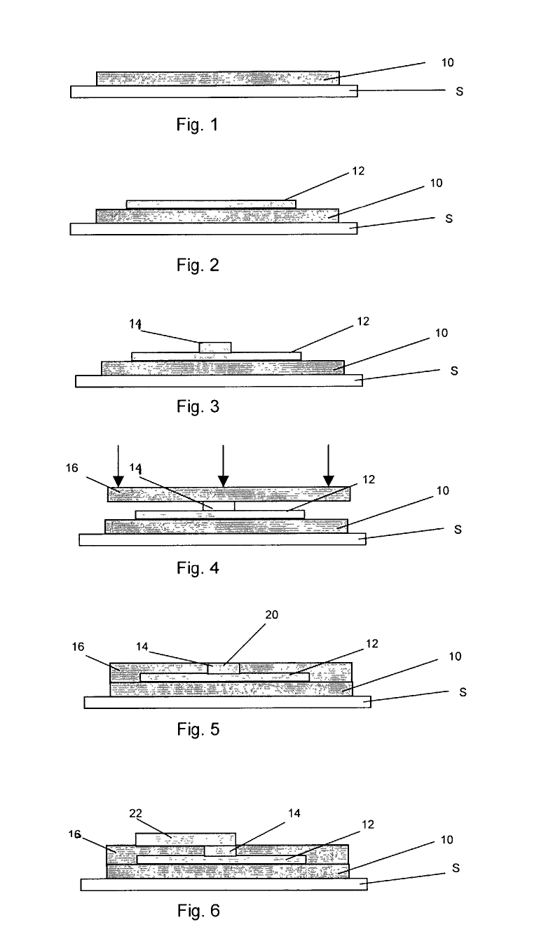

In one aspect of this invention, as illustrated in FIG. 1, a first electrically nonconductive layer 10 comprising a dry ceramic material is formed on a substrate S. The layer 10 may replace the substrate S or be a part of the substrate S. In the illustrated embodiment, the layer 10 comprises a prefabricated dry ceramic material, such as a commercially available CGS made of ceramic powders and binders (including, acrylic polymer, polyvinyl butyral resin, plasticizer, surfactants, flow modifiers). The CGS comprises 40-95% by weight of ceramic powders. The organic binders make up the rest. The ceramic sheet has a thickness of 3 to 100 microns, and should be soft enough at the lamination temperature and pressure to allow the penetration of dots without smearing, as described below. An example of a CGS suitable for use in the present inventive process is 85% ceramic powder and 15% polymer binder. Instead of a CGS, the ceramic layer 10 may be formed by other means such as tape casting, extrusion, and UV curing processes for example without departing from the scope and spirit of the present invention.

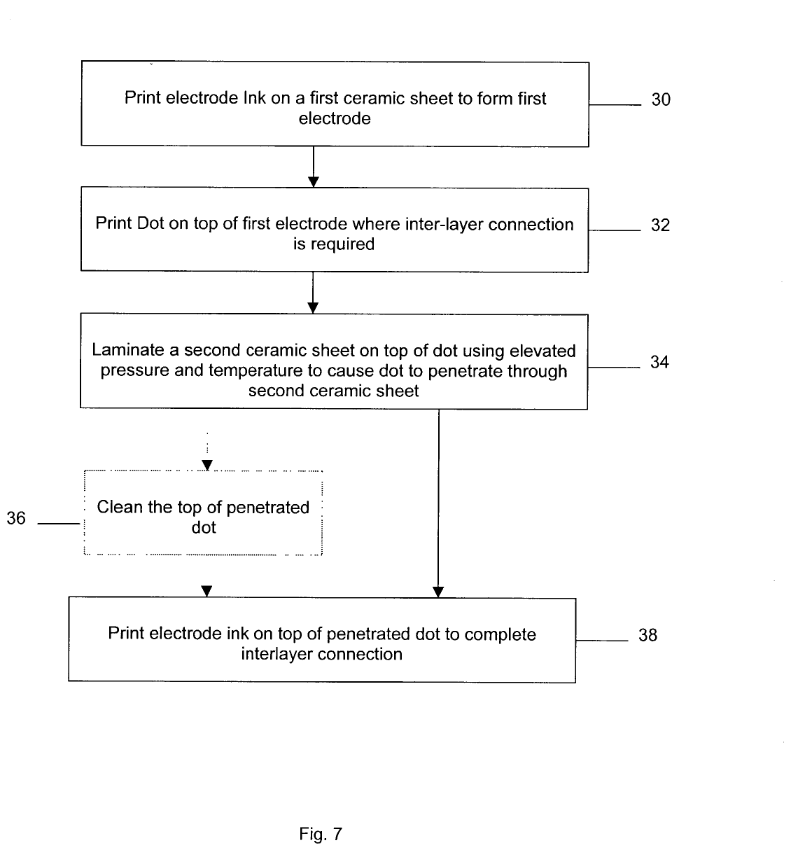

Then, as illustrated in FIG. 2, a first electrode 12 is formed onto the ceramic layer 10. (Step 30 in FIG. 7.) It is necessary to cure the ceramic layer prior to forming the electrode in order to prevent smearing of the non-cured ceramic layer when forming the electrode. The electrode 12 may be formed by printing and drying or curing conductive ink, such as a composition comprising a radiation curable binders such as ultraviolet/electron beam curable binders and metal powder. An ultraviolet/electron beam forming process for multi-layer electronic components and products thereof is disclosed in co-pending utility patent application Ser. No. 09/996,469, which application is fully incorporated by reference herein as if fully set forth herein.

As illustrated in FIG. 3, at the location where the interlayer electrical connection is to be made according to one embodiment of the present invention, ink made of metal powder in binders is printed as a dot 14 on top of the electrode that needs the connection. (Step 32 in FIG. 7.) The binders may include radiation curable binders, such as UV/E beam curable binders. The electrode inks for dot connections are made of 50-97% metal powders (such as nickel, copper, silver, gold, platinum, or palladium). The organic binders, between 3-50% by weight of the inks, include polymers, oligomers, monomers, photoinitiators, catalysts, plasticizers, flow modifiers, organic solvents, or water. The binders can be hardened by different methods (e.g., curing, drying or subject to ultra violet radiation, electron beam, heat, solvents, and other hardening processes). The hardened electrode inks for dot connection have high mechanical strength at elevated temperature. The step 32 in FIG. 7 is completed.

The electrode 12 may be formed using the same type of binder materials as that used to form the dot 14 or different materials.

Then, as illustrated in FIG. 4, a second layer 16 of CGS is laminated on top of the conducting dot 14. (Step 34 in FIG. 7.) The ceramic layer 16 may be of the same composition as the CGS layer 10, though it is not necessary that they have the exact same composition of ceramic powder and binders. Since the hardened conducting dot 14 for connection is solid with high mechanical strength, subsequent CGS laminating processes will not smear the dot 14. The lamination process can be accomplished in a press or an isostatic laminator. The lamination temperature is between 40 to 120 C, and the pressure is between 1000 psi to 20,000 psi. In the preferred embodiment, lamination is performed at approximately 80 C and 3000 psi. FIG. 5 shows the dot 14 fully penetrated through ceramic layer 16 following the lamination process. Step 34 in FIG. 7 is now completed. A subsequent process to clean the top of the dots by chemical or physical means can ensure reliable connections between the dots and the electrodes on top.

On the top 20 of the dot 14, another electrode 22 is formed. (Step 38 in FIG. 7.) The electrode 22 may be formed by printing metal ink made of conductive powder in radiation curable binders, such as UV/E beam curable binders, or other binders that may be hardened using other means (drying, heat, or other hardening means). In such a way, an interlayer connection of two electrodes 12 and 22 on the top and the bottom, respectively, of the ceramic layer 16 is made via the dot 14, as illustrated in FIG. 6, and step 38 in FIG. 7. Prior to forming the top electrode 22, the top 20 of the dot 14 may be cleaned to provide better contact with the top electrode 22 (optional step 36 in FIG. 7).

The multi-layer structure so formed is finally subject to a binder burnout process to remove/decompose the binders and a firing process to sinter the ceramic powder and the metal powder to provide the desired physical and electrical properties for the multi-layer component. The inter-layer electrical interconnection can be strengthened by metal diffusion during the firing or sintering process. It will also be understood and appreciated by those skilled in the art that the ink dots and layers used in the present invention may have conductive or non-conductive properties when initially printed depending on the particular technical application, or may obtain or enhance conductive properties after the penetration and lamination process during the final burnout and sintering step without departing from the spirit and scope of the present invention.

It is noted that for each layer described above, it may or may not cover the entire layer below. For example, the electrode layer may cover the underlying ceramic layer in a pattern that does not fully cover the ceramic layer, in the form of narrow electrical traces. The dot covers only a small area where the via is to be formed.

FIG. 7 is a block diagram of the dot penetration process of the present invention. The basic process steps described above may be repeated in several iterations to form multiple interconnecting electrodes and ceramic layers.

It can be appreciated that the invented dot penetration method for manufacturing multi-layer products with interlayer electrical connections can be performed by using ceramic sheets, and inks of different compositions. At least one of the dot penetrated layers (or a portion thereof) remains a part of the finished electronic component.

The process of the present invention may be implemented to form different types of electronic components, for use either standing alone, or integrated or combined with other passive and/or active components to form larger components, including but not limited to electrical devices, electronic devices, solid state devices, semi-conductor device, opto-electonic devices (such as LCD displays), etc. It is understood that the present invention may be implemented to process many different types of devices without departing from the scope and spirit of the present invention.

While the present invention has been described with respect to the preferred embodiments for achieving this invention's objectives, it will be apparent to those in the skilled art that various modifications and improvements may be made without departing from the scope and spirit of the invention. For example, while the layers deposited on the substrate are described above in accordance with specific embodiments, the described layers may be interchanged or different. For example, the electrode layer may be the first layer formed on the substrate. Accordingly, the disclosed embodiments are to be considered merely as illustrative of the invention.

What is claimed is:

1. A process of forming a multi-layer electronic component on a substrate, comprising the steps of:
forming a first layer that comprises conductive material for forming a conductive layer;
forming a connection structure on the second layer, said connection structure comprises a conductive material for forming a conductive connection dot;
forming a second layer over the connection structure and first layer, said second layer comprises a non-conductive material for forming a non-conductive layer, such that the connection structure penetrates through the second layer.

2. The process of claim 1, wherein the step of forming the second layer over the connection structure and first layer comprises the step of laminating the second layer under elevated pressure.

3. The process of claim 1, further comprising the step of forming a third layer on the second layer, connecting to the connection structure, said third layer comprises a conductive material for forming a conductive layer.

4. The process of claim 1, wherein the second layer comprises a ceramic material.

5. The process of claim 4, wherein the second layer comprises a ceramic green sheet.

6. The process of claim 1, further comprising the step of forming a fourth layer prior to forming the first layer, said fourth layer comprises a non-conductive material for forming a non-conductive layer.

7. The process of claim 6, wherein the second and fourth layers each comprises a ceramic green sheet.

8. The process of claim 6, wherein the substrate comprises the fourth layer at its top surface.

9. The process of claim 3, wherein the first or third layer comprises a pattern corresponding to a pattern of electrodes when the conductive layer is formed.

10. The process of claim 1, wherein the connection structure comprises conductive ink, and the step of forming the connection structure comprises printing and hardening the conductive ink on the first layer.

11. The process of claim 10, wherein the conductive ink comprises at least one of a radiation curable binder, a heat curable binder, a water based binder and a solvent based binder.

12. The process of claim 1, further comprising the step of firing or sintering the layers formed for forming the conductive and non-conductive layers and the connection dot.

13. The multi-layer electronic component as in claim 1, wherein the component is a part of a larger electronic component.

14. The multi-layer electronic component as in claim 1, further comprising the step of removing residual material of the second layer on top of the connection structure to facilitate connection of the third layer.

15. A multi-layer electronic component, formed in accordance with the process of claim 1.

16. A process of forming a multi-layer electronic component having interconnecting conductive layers, comprising the steps of:
providing a substrate;
forming a first ceramic green sheet above the substrate;
forming a first layer above the ceramic green sheet, corresponding to a first conductive layer, said layer comprises a conductive material;
forming a connection structure on the first layer, corresponding to a conductive connection dot, said connection structure comprises a conductive material;
laminating a second ceramic green sheet over the connection structure and the first layer;
forming a second layer above the second ceramic green sheet, corresponding to a second conductive layer and connecting to the connection structure, said second layer comprises a conductive material.
